(19) United States
(12) Patent Application Publication
(10) Pub. No.: US 2014/0326299 A1
(43) Pub. Date: Nov. 6, 2014

(54) SOLAR CELL WITH AN INTERMEDIATE BAND COMPRISING NON-STRESSED QUANTUM DOTS

(71) Applicants: Elisa Antolín Fernández, Madrid (ES); Antonio Martí Vega, Madrid (ES); Antonio Luque López, Madrid (ES); Íñigo Ramiro González, Madrid (ES); Pablo García-Linares Fontes, Madrid (ES)

(72) Inventors: Elisa Antolín Fernández, Madrid (ES); Antonio Martí Vega, Madrid (ES); Antonio Luque López, Madrid (ES); Íñigo Ramiro González, Madrid (ES); Pablo García-Linares Fontes, Madrid (ES)

(21) Appl. No.: 14/128,553

(22) PCT Filed: May 10, 2012
(86) PCT No.: PCT/ES2012/000133

§ 371 Date: May 7, 2014

(30) Foreign Application Priority Data
Jun. 21, 2011 (ES) P201100708

(51) Int. Cl. H01L 31/0352; H01L 31/18

(52) U.S. Cl. CPC H01L 31/035218; H01L 31/1892
USPC 136/255; 438/95

(57) ABSTRACT

An intermediate band solar cell is provided. The intermediate band material of the intermediate band solar cell consists of a collection of quantum dots of a semiconductor material that are immersed in a volume of a second semiconductor material. The first semiconductor material has a rock salt-type crystalline structure, and the second semiconductor material has a zinc blende structure. The quantum dots are produced by the immiscibility of the first semiconductor material in the second semiconductor material. A combination of the first and second semiconductor materials with a very similar lattice constant can therefore be selected such that the layer of intermediate band material does not have mechanical stress accumulation.

### CROSS REFERENCE TO RELATED APPLICATIONS

This application is a U.S. National-Stage entry under 35 U.S.C. §371 based on International Application No. PCT/ES2012/000133, filed May 10, 2012, which was published under PCT Article 21(2) and which claims priority to Spanish Patent Application No. P201100708, filed Jun. 21, 2011, which are all incorporated herein in their entirety by reference.

### TECHNICAL FIELD

The technical field relates to energy technology (solar photovoltaic converters), aerospace technology (photovoltaic converters), telecommunications engineering medicine (radiation sensors), and laboratory instruments (photodetectors).

### BACKGROUND

An intermediate band solar cell is described in International Publication No. WO/2000/077829 (Intermediate Band Semiconductor Photovoltaic Solar Cell). FIG. 1 illustrates the design (1) and simplified band diagram in operation (2). The operation of intermediate band solar cells is based on the use of an intermediate band material (3). Said material resembles a semiconductor material, but it differs in that it includes an electronic band (4) in addition to the conduction band (5) and valence band (6). The band (4) is called an intermediate band and is located inside what would be the band gap (hereinafter, gap) in a conventional semiconductor. As described in International Publication No. WO/2000/077829, to complete the device the intermediate band material (3) is placed between two conventional semiconductor layers, an n-type layer (7) and another p-type layer (8), commonly called emitters.

The intermediate band solar cell has better features than conventional solar cells with a single gap because as a result of the intermediate band, it is possible to absorb photons with lower energy than that of the gap of the semiconductor. Additional absorption (FIG. 1) would be performed by means of the absorption of photons, such as (9), which cause transitions from the valence band (6) to the intermediate band (4), and of photons, such as (10), which cause transitions from the intermediate band (4) to the conduction band (5). This absorption is added to the conventional absorption, whereby photons, such as (11), cause transitions from the valence band (6) to the conduction band (5). In the intermediate band solar cell, this additional absorption translates into a higher electric current without significant stress loss and, therefore, greater efficiency.

There are therefore at least two basic requirements for the intermediate band material (3): (i) it must have considerable absorption in the transitions (9) and (10) in order to produce a significant increase in photocurrent; (ii) it must not have an excessive non-radiative recombination so that the output voltage does not degrade.

The intermediate band materials that have been proposed until now can be categorized in two groups: those in which the energy levels giving rise to the intermediate band are generated by introducing atomic impurities in a semiconductor and those in which the confined levels generated by quantum dots are used for such purpose. The materials and devices described in International Publication No. WO/2005/055285 (Multiband Semiconductor Compositions for Photovoltaic Devices) and Spanish Application No. P200900461 (Method for the Production of a Silicon Intermediate Band Solar Cell), for example, belong to the first type. To prevent such implementation with atomic impurities from going though an excessive non-radiative recombination, the method patented in Spanish Patent No. ES2276624 (Method for the Suppression of Non-radiative Recombination in Materials Doped with Deep Centers) has been proposed. In contrast, the implementation with quantum dots theoretically does not have the inherent problem of non-radiative recombination because quantum dots do not have the same vibration modes as impurities and can therefore behave in an essentially radiative manner. However, the quantum dot materials used until now do not have the properties required for this application due to the reasons that will be described below.

FIG. 2 illustrates the operation of an intermediate band solar cell based on the use of quantum dots. Quantum dots are nanometric-sized three-dimensional structures (12) made of a small gap semiconductor material that are embedded in a matrix of another larger gap semiconductor (13), generally called a barrier material. Due to their small size, quantum dots generate potential wells (14) introducing discrete energy levels (confined levels) into the gap of the matrix material. These levels act as an intermediate band (4).

Quantum dot material systems used until now to manufacture intermediate band cells (generally InAs in the quantum dot and GaAs for the barrier, the latter with the addition of P or N in some cases) are produced by the Stranski-Krastanov method. This means that the two materials used have a different atomic lattice parameter and that when one material is epitaxially deposited on the other, stress is generated between them. The dots are produced spontaneously to reduce that stress. However, stress affects the band diagram of the structure.

This is illustrated in FIG. 3. Two materials considered independently, one with a large gap (18) and another with a small gap (21), are depicted in the band diagram (15). (5) and (6) are the conduction and valence bands of the first material, respectively; (19) and (20) being those of the second material. The resulting band diagram if a quantum dot is manufactured with these two materials can be seen in (16) and there is stress due to their different lattice constants. The gap of the dot material widens (22) as a result of the stress.

Furthermore, the dot deforms (no longer having an aspect ratio close to 1), loses confinement in some directions, and many confined states are generated for holes (23) and for electrons (24). This situation has several damaging consequences for the operation of the intermediate band cell, among them: the intermediate band (4) is too close to the conduction band (5) such that the optical transition [(10) in FIG. 1] has too little energy to contribute to an efficient exploitation of the solar spectrum; the escape/recombination between the intermediate band (4) and the conduction band (5) is too fast at room temperature, which hinders maintaining a high voltage in the device. The fact that it is impossible to grow many quantum dot layers because stress accumulates and there are crystalline defects acting as non-radiative recombination promoters must be added to the foregoing. Therefore, the absorption of photons in the transitions (9) and (10) is very limited. For all these reasons and based on current experimental evidence, it is known that intermediate band cells manufactured with InAs/GaAs quantum dots behave according to the model of an intermediate band cell at low temperatures, but not at room temperature.

In addition, other objects, desirable features and characteristics will become apparent from the subsequent summary and detailed description, and the appended claims, taken in conjunction with the accompanying drawings and this background.

### SUMMARY

According to various embodiments, the present disclosure provides an intermediate band solar cell using another type of quantum dots where the dot material and the barrier material have a very similar atomic lattice parameter. In FIG. 3, (17) represents the band diagram of a quantum dot of lattice matching materials, again assuming that the materials used have gaps shown in (15). In this case, the gap of the dot material is not considerably altered (21). Furthermore, the dots can be small and spherical, so the number of confined states (23) and (24) can be minimized

This results in the appearance of a fundamental confined level (25) that is well separated from the other confined states (23) and from the conduction band (5) and valence band (6). The levels (25) of the set of quantum dots can be used efficiently as an intermediate band. On the other hand, the set of dots can be much greater (greater optical absorption) because since stress does not accumulate, crystalline quality is not compromised. If the alignment of bands between dot and barrier semiconductor is different, a confined state of holes (24) could be used for generating the intermediate band.

Self-assembled quantum dots cannot be produced in the Stranski-Krastanov mode when the semiconductors are lattice matched. To manufacture a dot material of this type, the use of semiconductors which, while having the same lattice parameter, do not have the same crystalline structure is proposed. In one example, the use of a compound or semiconductor alloy having a halite- or rock salt-type crystalline structure (cubic hexoctahedral) is proposed for the quantum dots and a compound or semiconductor alloy having zinc blende-type crystalline structure (cubic hextetrahedral) is proposed for the barrier material. Group IV-VI PbS, PbSe and PbTe semiconductors (the Pb therein could be partially substituted with Sn) belong to the first group. The compounds and alloys of the II-VI family (Zn, Cd, Mg) (S, Se, Te) in zinc blende structure crystallizations (the cation could be partially substituted with Mn, Be or Ca) belong to the second group. Depending on the chosen elements, suitable stoichiometries in the compound of the quantum dot and the compound of the barrier material must be determined so that they have a very similar lattice parameter and for optimizing the energy of the transitions (9), (10) and (11) [FIGS. 1 and 2]. For an efficient absorption of photons both in transition (9) and in transition (10), it will generally be necessary to dope the quantum dots so that they are half-filled with electrons (introducing the doping species specifically in the dots or in the barrier material). Dots of different sizes may be produced in the same device for generating multiple energy transitions if it is considered advantageous.

In this method the quantum dots are produced by the immiscibility of the group IV-VI semiconductor having a rock salt structure in the matrix of the group II-VI semiconductor having a zinc blende structure. This means that if layers of one material are grown alternated with layers of the other material, the layers of the group IV-VI material spontaneously transform into quantum dots, generally centrosymmetric dots, to minimize surface energy. The quantum dots can be precipitated by applying an annealing on the structure of alternate layers or, they can self-assemble during the growth of the layers under suitable temperature and pressure conditions of the elements. Another way to generate these quantum dots through lattice type mismatching is by introducing the group IV element, for example, Pb, in the matrix semiconductor by means of ion implantation and then subjecting the material to an annealing.

FIG. 4 depicts the structure of an intermediate band solar cell manufactured by the various teachings of the present disclosure. (27) is the substrate, i.e., the semiconductor wafer on which the solar cell is grown epitaxially. (26) is the buffer layer, i.e., the first epitaxially grown layer, which absorbs the defects and stresses of the interface and serves for gradually adapting the lattice parameter to that of the material that will be used in the device. Group II-VI zinc blende materials have the advantage of being able to grow devices with them that have an excellent crystalline quality by using substrates with a very different lattice parameter if a suitable buffer layer is used. (7) is the first emitter to be grown, which can be made of the material chosen as a barrier or of another material (generally with an identical or larger gap, because it would otherwise limit the voltage of the device). The same can be applied to the front emitter (8). In principle, putting the emitter n in the front position and emitter p in the back position, or vice versa, is equally valid. This decision will be made depending on what is the most advantageous for the carrier dynamics in the device and taking into account the ease of manufacture. On the other hand, the emitters can be completed with a layer with high doping or a larger gap to minimize the surface recombination speed, as in conventional solar cells (a layer called window in the case of the front emitter, or back surface field—BSF—for the back emitter).

Continuing with FIG. 4, (3) represents the intermediate band material, which in this disclosure contains the quantum dots (12) made of group IV-VI material in the zinc blende matrix made of group II-VI material (13) with the suitable doping level to half-fill the dots. Layers with low doping (not depicted in the drawing) can also be included between one or both of the emitters and the quantum dot material to prevent the quantum dots from being located inside the charge area of the space of the device. Finally, to extract the electric power generated by the cell it will be necessary to deposit a front metallic contact (28) and another back metallic contact (29).

A person skilled in the art can gather other characteristics and advantages of the disclosure from the following description of exemplary embodiments that refers to the attached drawings, wherein the described exemplary embodiments should not be interpreted in a restrictive sense.

### BRIEF DESCRIPTION OF THE DRAWINGS

FIG. 1 shows the layer structure of an intermediate band solar cell and the band diagram corresponding to the structure shown in when the device is in operation.

FIG. 2 shows the layer structure of an intermediate band solar cell implemented with quantum dots and the band diagram corresponding to the structure shown in when the device is in operation.

FIG. 3 shows simplified band diagrams of: two materials, one with gap and another with gap, considered independently; a quantum dot of the material with gap in the material with gap taking into account stress effects; and a quantum dot of the material with gap in the material with gap without stress effects.

FIG. 4 shows the layer structure of a quantum dot intermediate band solar cell that is manufactured according to various embodiments. The structure includes, in addition to the fundamental layers shown in FIG. 2, other necessary elements to complete the device, such as the substrate, the buffer layer, and the front contact and back contact.

FIG. 5 shows a possible process for producing the layer structure of the quantum dot intermediate band solar cell that is manufactured according to various embodiments.

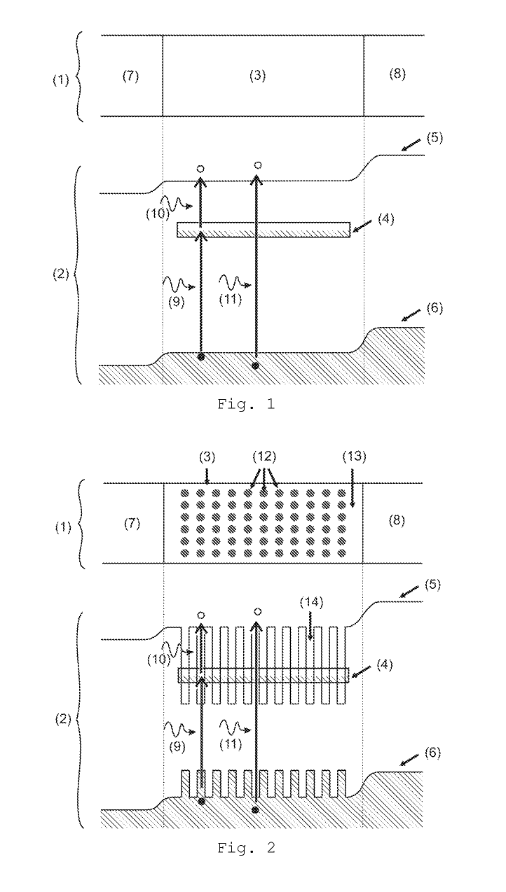

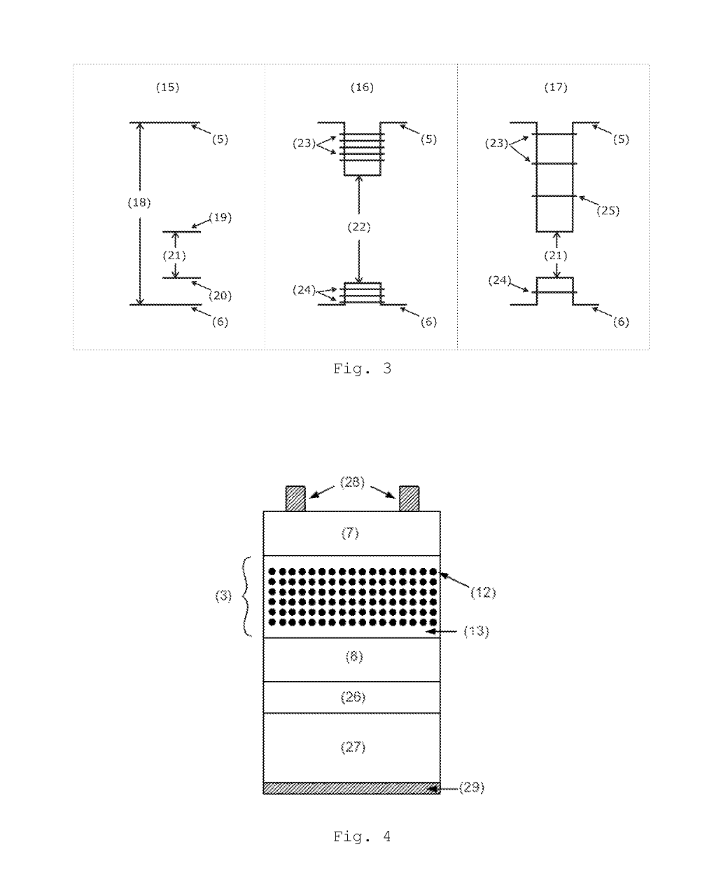

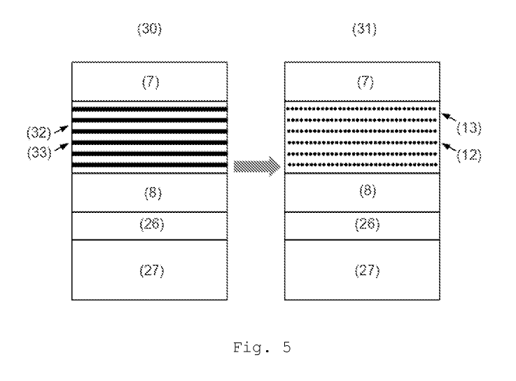

### DETAILED DESCRIPTION

The following detailed description is merely exemplary in nature and is not intended to limit the invention or the application and uses of the present disclosure. Furthermore, there is no intention to be bound by any theory presented in the preceding background or the following detailed description.

According to various embodiments, the manufacture of an intermediate band solar cell using PbTe quantum dots in a Cd_{0.7}Mg_{0.3}Te matrix will be described as an exemplary case, although as mentioned in the preceding section, the range of materials that can be used is very wide. The PbTe/Cd_{0.7}Mg_{0.3}Te system meets the following conditions: the two materials are immiscible due to the different crystalline structure, have the same lattice constant, and the gaps are suitable to produce an intermediate band cell. In this example, a design in which the front emitter is an n-type emitter is chosen because it is hard to carry out a p-type doping with Cd(Mg)Te and would therefore result in an emitter that is too resistant for current extraction through the front metal mesh. Alternatively, a p-on-n type structure could be made by adding ZnTe to the composition of the front emitter to facilitate p-type doping.

FIG. 5 illustrates the most relevant part of the method of manufacture. If possible, epitaxial growth of the semiconductor structure will be carried out in a molecular beam epitaxy (MBE) reactor with two independent chambers. Generally, in FIG. 5 (30) represents a first step consisting of the epitaxial growth of a semiconductor structure by combining several materials in alternate layers [(32) and (33)], and (31) represents the precipitation of the quantum dots (12) inside the volume of barrier material (13) after an annealing process.

First, a Si, GaAs or Ge wafer is used as a substrate. The surface is degassed, cleaned and prepared with plasma etching in a chamber which is not that used for growing group II-VI and IV-VI materials. The substrate is a highly doped p-type substrate (about 2 10¹⁸ cm ⁻³).

Second, the substrate is transferred to the second chamber of the MBE reactor, where a buffer layer is grown with a (Cd,Mg)Te alloy having a thickness of 500 nm. It is doped with N to obtain the highest possible p-type concentration (>2 10¹⁷ cm⁻³).

Third, the p-type emitter made of Cd_{0.7}Mg_{0.3}Te:N with a doping of 2 10¹⁷ cm⁻³ and a thickness of 500 nm is grown.

Fourth, a stack of 200 repetitions of alternate layers of 1 nm PbTe [FIG. 5 (33)] and 10 nm Cd_{0.7}Mg_{0.3}Te [FIG. 5 (32)] is grown at a temperature less than 300° C. I is digitally introduced in the growth of the layers of Cd_{0.7}Mg_{0.3}Te (a delta-doping layer of I per layer of material).

Fifth, the n-type emitter made of Cd_{0.7}Mg_{0.3}Te:I with a doping of 2 10¹⁸ cm⁻³ and a thickness of 500 nm is grown.

Sixth, with reference to FIG. 5, the grown structure (30) is annealed at temperature between 350 and 450° C. to cause (31) the precipitation of the PbTe quantum dots (12) in the Cd_{0.7}Mg_{0.3}Te matrix (13).

Seventh, layers of gold are deposited by evaporation to form the back metallic contact and front metallic contact. Photolithography techniques are used for depositing the front contact in the form of a mesh that allows light to pass.

The industrial application of the present disclosure comprises all the characteristic uses of photovoltaic devices such as generators for generating electric power from solar radiation, namely:

Manufacturing photovoltaic converters for the aerospace industry. Satellites usually use photovoltaic panels for energy self-sufficiency. The teachings of the present disclosure would be especially useful in this application because since it is more efficient than conventional cells, it would require less panel surface area and therefore less weight during launch, for providing the same electric power.

Manufacturing photovoltaic converters for use in land concentration systems.

Concentration systems use lenses or mirrors to focus sunlight on a photovoltaic cell having a small surface area. For these systems to be profitable, the cell must have a minimal conversion efficiency that justifies the implementation of optical concentration components. On the other hand, if high efficiency solar cell technology is provided, the exploitation thereof will generally be more profitable if concentration systems are implemented (because the power generated by the cells is maximized and because the surface area of the cell used is minimized). The patented solar cell is suitable for use in concentration systems since it is a high efficiency cell. Due to their technical particularities, these systems are suitable for the massive generation of electricity (photovoltaic plants) and not for distributed generation in non-optimized locations (e.g., in architectural integration).

Manufacturing photovoltaic converters for use in flat land systems (without concentration). Today, this is the most widespread industrial application of solar cells, used both in power plants and in a distributed manner. Flat panels are the most well known among electricity generating systems and the flat panel industry is better established than that of concentration systems. However, the surface area of the photovoltaic device required for generating the same electric power is larger, and therefore not all photovoltaic device technologies have a competitive cost when implemented in flat panels. The solar cell according to the present disclosure is suitable for use in flat photovoltaic systems, even though it may be necessary to introduce modifications in the method of manufacture in order to lower the costs in producing large surface areas for the device. In this sense, a critical element is the substrate. To manufacture cells intended for use in a flat panel it may be necessary to adapt the described method of manufacture to thin film manufacturing (non-epitaxial growth on a less expensive substrate, e.g., glass, brass, steel, plastic, etc.), or to maintain the epitaxial growth on the semiconductor substrate, but including a last step of recycling the substrate and replacing with a glass substrate in the described method.

Although the most relevant application of photovoltaic devices is the production of electricity from solar energy, there are other applications in which non-solar radiation is converted for which the patented device would also be suitable. Examples of these applications are power cogeneration (harnessing infrared radiation from very hot industrial elements to produce electricity) or radiation detectors for use in telecommunications and medical applications.

While at least one exemplary embodiment has been presented in the foregoing detailed description, it should be appreciated that a vast number of variations exist. It should also be appreciated that the exemplary embodiment or exemplary embodiments are only examples, and are not intended to limit the scope, applicability, or configuration of the present disclosure in any way. Rather, the foregoing detailed description will provide those skilled in the art with a convenient road map for implementing an exemplary embodiment, it being understood that various changes may be made in the function and arrangement of elements described in an exemplary embodiment without departing from the scope of the present disclosure as set forth in the appended claims and their legal equivalents.

1. An intermediate band solar cell in which the intermediate band material is a quantum dot material, comprising:
a dot material for forming quantum dots that is a compound or semiconductor alloy having a halite- or rock salt-type crystalline structure; and
a barrier material containing the quantum dots is a compound or semiconductor alloy having a zinc blende-type crystalline structure,
wherein the dot material and the barrier material are lattice matched materials to prevent mechanical stress accumulation in the intermediate band material.

2. The intermediate band solar cell according to claim 1, wherein the dot material forming the quantum dots is a compound or semiconductor alloy containing at least one group IV element the periodic table, Pb and Sn, as a cation.

3. The intermediate band solar cell according to claim 1, wherein the levels confined in quantum dots for electrons or for holes are used as an intermediate band.

4. The intermediate band solar cell according to claim 1, further comprising quantum dots of different sizes inside the device for generating multiple energy optical transitions.

5. The intermediate band solar cell according to claim 1, wherein a plurality of emitters are made of the same semiconductor material that is used as the barrier material of the quantum dots.

6. The intermediate band solar cell according to claim 1, wherein a front emitter is a p-type emitter and a rear emitter is an n-type emitter.

7. The intermediate band solar cell according to claim 5 comprising one or more layers with low doping between at least one of the plurality of emitters and the dot material to prevent the quantum dots from being located inside the charge area of the space of the intermediate band solar cell.

8. A method of manufacturing an intermediate band solar cell, comprising:
forming quantum dots by self-assembly during the epitaxial growth of a semiconductor layer structure on a semiconductor substrate.

9. The method of manufacturing an intermediate band solar cell according to claim 8, wherein the semiconductor substrate is replaced with a substrate selected from the group comprising a glass substrate, a brass substrate, a steel substrate, and a plastic substrate.

10. The intermediate band solar cell according to claim 1, wherein the barrier material hosting the quantum dots is a compound or semiconductor alloy containing at least one of the elements Zn, Cd, Mg, Mn, Be, Ca, as a cation.

11. The intermediate band solar cell according to claim 1, wherein the barrier material hosting the quantum dots is a compound or semiconductor alloy containing at least one group VI element of the periodic table, S, Se and Te, as an anion.

12. The intermediate band solar cell according to claim 1, wherein the dot material forming the quantum dots is a compound or semiconductor alloy containing at least one group VI element of the periodic table, S, Se and Te, as an anion.

13. The intermediate band solar cell according to claim 1, wherein a plurality of emitters are made of a semiconductor material with a gap equal to or greater than that of the barrier material.

14. The intermediate band solar cell according to claim 13, wherein the plurality of emitters are each made of an identical semiconductor material.

15. The intermediate band solar cell according to claim 13, wherein the plurality of emitters are each made of a different semiconductor material.

16. The intermediate band solar cell according to claim 6, wherein at least one of the front emitter and rear emitter include a layer with higher doping or a larger gap to reduce their surface recombination speed.
